(19) United States
(12) Patent Application Publication
(10) Pub. No.: US 2026/0227716 A1
(43) Pub. Date: Aug. 6, 2026

(54) SYSTEM FOR SUPPORTING A PELLICLE IN A LITHOGRAPHIC APPARATUS, ALLOWING FOR PRESSURE INCREASE IN A REGION BETWEEN THE PELLICLE AND A PATTERNING DEVICE

(71) Applicant: ASML NETHERLANDS B.V., Veldhoven (NL)

(72) Inventors: Emericus Antoon Theodorus VAN DEN AKKER, Veldhoven (NL); Zhuangxiong HUANG, Eindhoven (NL); Cem DEMIRKESEN, Veldhoven (NL); Syed Aaquib HAZARI, Eindhoven (NL)

(73) Assignee: ASML NETHERLANDS B.V., Veldhoven (NL)

(21) Appl. No.: 19/154,778

(22) PCT Filed: Feb. 1, 2024
(86) PCT No.: PCT/EP2024/052496

§ 371 Date: Aug. 7, 2025

(30) Foreign Application Priority Data
Mar. 6, 2023 (EP) 23160143.6

(51) Int. Cl. G03F 7/00

(52) U.S. Cl. CPC G03F 7/70983; G03F 7/70866

(57) ABSTRACT

A pellicle support system for use in a lithographic apparatus, the system including: a pellicle; a pellicle support arranged to secure the pellicle relative to the surface of a patterning device so that an enclosed region is defined between the pellicle and the patterning device; and at least one conduit arranged to supply fluid to the enclosed region for increasing the pressure in the enclosed region.

### CROSS-REFERENCE TO RELATED APPLICATIONS

This application claims priority of EP application 23160143.6 which was filed on 6 Mar. 2023, and which is incorporated herein in its entirety by reference.

### FIELD

The present invention relates to a system for supporting a pellicle in a lithographic apparatus. Embodiments of the system increase the pressure in the region between the pellicle and a patterning device. This may reduce the magnitude of the pressure differences that may occur across the pellicle and thereby increases the pellicle lifetime.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$C D = {k}_{1} * \frac{λ}{N A} \qquad ( 1 )$$

where λ is the wavelength of the radiation used, NA is the numerical aperture of the projection system used to print the pattern, k1 is a process-dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

A lithographic apparatus includes a patterning device (e.g., a mask or a reticle). Radiation is provided through, or reflected off, the patterning device to form an image on a substrate. A pellicle may be provided to protect the patterning device from airborne particles and other forms of contamination. Contamination on the surface of the patterning device can cause manufacturing defects on the substrate. The pellicle for protecting the patterning device may be called a pellicle.

The pellicle may be damaged by the pressures that it experiences during use. This may shorten the lifetime of the pellicle.

It is generally desirable to improve on known systems for supporting a pellicle.

### SUMMARY OF THE INVENTION

According to a first aspect of the invention, there is provided a pellicle support system for use in a lithographic apparatus, the system comprising: a pellicle; a pellicle support arranged to secure the pellicle relative to the surface of a patterning device so that an enclosed region is defined between the pellicle and the patterning device; and at least one conduit arranged to supply fluid to the enclosed region for increasing the pressure in the enclosed region.

According to a second aspect of the invention, there is provided a lithographic apparatus comprising the pellicle support system according to the first aspect.

According to a third aspect of the invention, there is provided a method for performing lithography, the method comprising projecting a radiation beam through a low pressure environment onto a substrate in an exposure operation; wherein the radiation beam passes through a pellicle located in the low pressure environment; and the pellicle is comprised by the pellicle support system according to the first aspect.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 is a more detailed view of the lithographic apparatus;

FIG. 3 schematically depicts, in cross-section, part of a pellicle according to an embodiment of the invention;

FIG. 4 schematically depicts a pellicle support system according to a first embodiment of the invention; and

FIG. 5 schematically depicts a pellicle support system according to a second embodiment of the invention.

### DETAILED DESCRIPTION

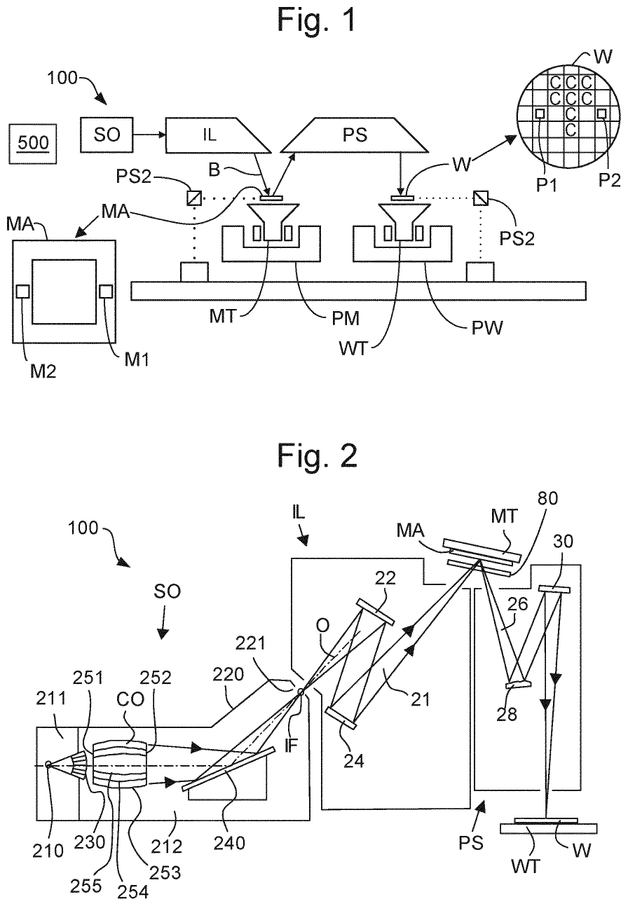

FIG. 1 schematically depicts a lithographic apparatus 100 including a source collector module SO according to one embodiment of the invention. The apparatus 100 comprises:
an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

The patterning device MA may be transmissive or reflective. Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module SO may be separate entities, for example when a CO₂ laser is used to provide the laser beam for fuel excitation.

In such cases, the laser is not considered to form part of the lithographic apparatus 100 and the radiation beam B is passed from the laser to the source collector module SO with the aid of a beam delivery system comprising, for example, suitable directing mirrors and/or a beam expander. In other cases the source may be an integral part of the source collector module SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as sigma-outer and sigma-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212.

The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the source collector module SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

In an embodiment the lithographic apparatus 100 comprises a dynamic gas lock. The dynamic gas lock comprises a pellicle 80. In an embodiment the dynamic gas lock comprises a hollow part covered by a pellicle 80 located in the intervening space. The hollow part is situated around the path of the radiation. In an embodiment the lithographic apparatus 100 comprises a gas blower configured to flush the inside of the hollow part with a flow of gas. The radiation travels through the pellicle before impinging on the substrate W.

In an embodiment the lithographic apparatus 100 comprises a pellicle 80. As explained above, in an embodiment the pellicle 80 is for a dynamic gas lock. In this case the pellicle 80 functions as a filter for filtering JR radiation and/or DUV radiation. Additionally or alternatively, in an embodiment the pellicle 80 is pellicle for the patterning device MA for EUV lithography. The pellicle 80 of the present invention can be used for a dynamic gas lock or for a pellicle or for another purpose such as a spectral purity filter. In an embodiment the pellicle 80 comprises a membrane 40, which may also be called a membrane stack. In an embodiment the membrane is configured to transmit at least 80% of incident EUV radiation.

In an embodiment the pellicle 80 is configured to seal off the patterning device MA to protect the patterning device MA from airborne particles and other forms of contamination. Contamination on the surface of the patterning device MA can cause manufacturing defects on the substrate W. For example, in an embodiment the pellicle is configured to reduce the likelihood that particles might migrate into a stepping field of the patterning device MA in the lithographic apparatus 100.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

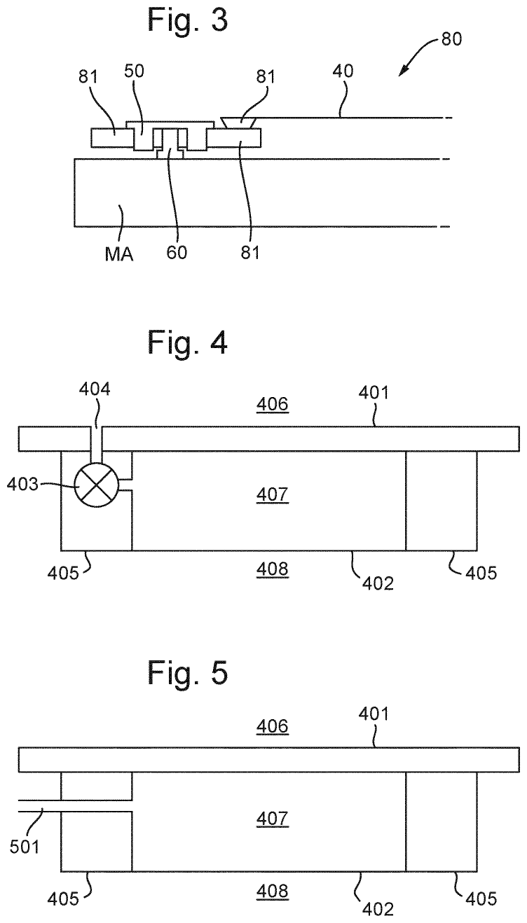

FIG. 3 schematically depicts, in cross-section, part of a pellicle 80 according to an embodiment of the invention. The pellicle 80 is for EUV lithography. The pellicle 80 comprises a membrane 40. The membrane 40 is transmissive for EUV radiation. Of course the membrane 40 may not transmit 100% of incident EUV radiation. As shown in FIG. 3, in an embodiment the membrane 40 is substantially planar. In an embodiment the plane of the membrane 40 is substantially parallel to the plane of the patterning device MA.

The pellicle 80 has a shape such as a square, a circle or a rectangle, for example. The shape of the pellicle 80 is not particularly limited. The size of the pellicle 80 is not particularly limited. For example, in an embodiment the pellicle 80 has a diameter in the range of from about 100 mm to about 500 mm, for example about 200 mm.

As depicted in FIG. 3, in an embodiment the pellicle 80 comprises a frame 81. The frame 81 is configured to hold the membrane 40. The frame 81 provides mechanical stability to the membrane 40. The frame 81 is configured to reduce the possibility of the membrane 40 being deformed away from its planar shape. In an embodiment, a pre-tension is applied to the membrane 40 during its manufacture. The frame 81 is configured to maintain the tension in the membrane 40 so that the membrane 40 does not have an undulating shape during use of the lithographic apparatus 100. In an embodiment the frame 81 extends along the perimeter of the membrane 40. The outer periphery of the membrane 40 is positioned on top of the frame 81 (according to the view of FIG. 3).

As depicted in FIG. 3, in an embodiment the frame 81 comprises a border portion directly connected to the membrane 40. As shown in FIG. 3, in an embodiment the frame 81 further comprises an extension portion that makes it easier for the pellicle 80 to be fixed relative to the patterning device MA. The border portion and the extension portion of the frame 81 may be adhered to each other.

As depicted in FIG. 3, in an embodiment the pellicle 80 comprises a fixture 50. The fixture 50 is arranged to be removably coupled to studs 60 fixed relative to the pattern device MA. Additional details of the assembly are described in WO 2016079051 A2, in particular in FIG. 11 and FIGS. 28 to 31 and the associated description.

Further details of pellicles 80, and support structures for pellicles 80, that may be used in embodiments are provided in U.S. Ser. No. 11/314,163B2 and WO 2020099072 A1, the entire contents of which are incorporated herein by reference.

Although not shown in FIG. 3, X-blades and Y-blades may be provided on the opposite side of the pellicle 80 to the patterning device MA. The X-blades and Y-blades may block EUV radiation and EUV radiation may pass through an opening between the X-blades and Y-blades. The X-blades and Y-blades may be moved so as to define the cross-sectional shape and dimensions of the EUV radiation beam that illuminates the patterning device MA.

A pellicle 80 is a very thin structure and it may be damaged if large pressure differences arise across it. The pressure difference across a pellicle 80 may cause the pellicle 80 to sag and this may cause the pellicle 80 to break.

The pressure difference across a pellicle 80 is dependent on its current state of use. During a calibration step, that may be referred to as a spring unloaded calibration, the X-blades and Y-blades are moved so that they are close to each other. The inventors have realized that during the spring unloaded calibration, a large pressure difference may arise across the pellicle 80 that may damage the pellicle 80. When a pellicle 80 is being used in a lithographic process, it may be moved quickly with the patterning device MA. A turnaround situation occurs whenever the direction of movement of the pellicle 80 is changed. The inventors have also realized that a large pressure difference may arise across the pellicle 80 during a turnaround situation.

Embodiments provide new techniques that increase the pressure in the region between the patterning device MA and a pellicle. This reduces the magnitude of the pressure differences that may occur across a pellicle and thereby increase the lifetime of the pellicle.

FIG. 4 schematically shows a pellicle support system according to a first embodiment. The pellicle support system comprises a pellicle 402 and a pellicle support 405.

The pellicle 402, that comprises a membrane, may be substantially the same as the known pellicle 80 as described earlier. Although not shown in FIG. 4, the pellicle support 405 may comprise a frame 81, fixture 50 and studs 60. The pellicle support 405 may, in plan view, surround the pellicle 402. The pellicle support 405 may be a single structure. Alternatively, the pellicle support 405 may comprise a plurality of separate structures.

As with known techniques, the pellicle 402 is secured relative to, and spaced apart from, a patterning device 401 such that the surface of the patterning device 401 for patterning radiation is covered by the pellicle 402. The patterning device 401 may be substantially the same as the known patterning device MA as described earlier.

As shown in FIG. 4, the base of the pellicle support 405 may be secured to the patterning device 401. However, embodiments also include the patterning device 401 being secured to a patterning device stage and the pellicle support 405 alternatively being secured to the patterning device stage.

There is a patterning device backside region 406 that is on an opposite side of the patterning device 401 to the pellicle 402. There is an illumination region 408 that is on an opposite side of the pellicle 402 to the patterning device 401. There is an enclosed region 407 between the pellicle 402 and the patterning device 401. The enclosed region 407 may be substantially bounded by the pellicle 402, the pellicle support 405, and the patterning device 401 (and in some embodiments part of the patterning device stage).

The enclosed region 407 may comprise small gaps, or vents, that provide a fluid flow path between the enclosed region 407 and the illumination region 408. The fluid flow path between the enclosed region 407 and the illumination region 408 may equalize the pressure between the enclosed region 407 and the illumination region 408. However, due to the restricted flow rate along the flow path and the fast changing circumstances of the pellicle 402, a pressure difference may still build up between the enclosed region 407 and the illumination region 408.

During a lithographic process, an EUV radiation beam, that has not been patterned, travels from the illumination region 408, through the pellicle 402, and into the enclosed region 407. The beam reflects off the patterning device 401 so that it becomes a patterned beam. The patterned beam then travels from the enclosed region 407, through the pellicle 402, and back into the illumination region 408. During the lithographic process, there may be a gas in the a patterning device backside region 406, that may be referred to as a backfill gas. The backfill gas may be, for example, hydrogen.

In the present embodiment, there is a conduit 404 that provides a fluid flow path between the patterning device backside region 406 and the enclosed region 407. There may also be a flow control device 403 for controlling the flow of fluid through the conduit 404. As described earlier, the patterning device backside region 406 comprises gas. The fluid flow through the conduit 404 may therefore be a gas flow, with the gas flow rate dependent on the flow control device 403. As shown in FIG. 4, the flow control device 403 may be provided in the fluid flow path of the conduit 404. However, the embodiments also include the flow control device 403 alternatively being located in, for example, the patterning device backside region 406.

The conduit 404 is a new feature that is not present in known systems. The conduit 404, allows some of the backfill gas to flow from the patterning device backside region 406 to the enclosed region 407. This increases the gas pressure in the enclosed region 407 from that in known techniques. The pressure of the enclosed region 407 may be increased by, for example, a pressure in the range of about 0.2 Pa to 5 Pa, and preferably about 1 Pa.

The gas pressure in the enclosed region 407 is dependent on the flow rate of gas through the conduit 404, the duration of the gas flow through the conduit 404, and the rate of any gas flow from the enclosed region 407 to the illumination region 408. The required flow rate of gas through the conduit 404 to increase the gas pressure in the enclosed region 407 may be very low due to the small volume for gas in the enclosed region 407. The flow rate of gas through the conduit 404 may be a lot less than the flow rate of gas to the patterning device backside region 406.

The flow rate, Q, of gas through the conduit 404 may be defined as:

$$Q = \frac{Δ P \cdot ER\_Volume}{T i m e c o n s t a n t}$$

### Where:

ΔP is a desired pressure increase of the enclosed region 407;
ER_Volume is the volume of the enclosed region 407; and
Timeconstant is the expected time that it takes a pellicle 402 to react to pressure changes in its surrounding environment.

The flow rate, Q, may be, for example, in the range of about 0.002 mbar·l/s to 1 mbar·l/s. If the desired pressure increase of the enclosed region 407 is 1 Pa, the volume of the enclosed region 407 is 0.00001 m³, and the Timeconstant is 0.01 s, the flow rate would be 0.01 mbar·l/s. The flow rate, Q, is dependent on the flow control device 403.

In a first implementation of the first embodiment, the flow control device 403 is an orifice with a fixed shape. The orifice may be a narrowing of, or obstruction in, the conduit 404. An advantage of the first implementation of the flow control device 403 is that it is simple to construct, it does not require any control and it is east to maintain. However, the first implementation of the flow control device 403 is unable to adjust the flow rate through the conduit 404.

In a second implementation of the first embodiment, the flow control device 403 is a variable valve so that the flow rate through the conduit 404 may be adjusted. An advantage of the second implementation of a flow control device 403 is that the pressure of the enclosed region 407 may be accurately set at a number of different pressure levels. The most appropriate pressure level may be dependent on the specific conditions that the pellicle 402 is expected to experience during its operation.

The conduit 404 between the patterning device backside region 406 to the enclosed region 407 may be provided in a number of different ways. For example, as shown in FIG. 4, the conduit 404 may be provided through the pellicle support 405. The pellicle support 405 may be secured to the patterning device 401, or a patterning device stage, by a number of feet, such as four feet. In a preferred embodiment, the conduit 404 may be provided through one of the feet of the pellicle support 405.

If the conduit passes through the patterning device 401, the patterning device 401 may differ from known patterning devices by comprising an opening so that the conduit 404 may pass through it. Such a modification may be made without substantial changes being required to most of the other features of the patterning device 401. In particular, the patterning surface of the patterning device 401 may remain unchanged.

If the patterning device 401 is secured to a patterning device stage and the conduit passes through the patterning device stage, the patterning device 401 may be the same as known patterning devices. The patterning device stage may differ from known patterning device stages by comprising an opening so that the conduit 404 may pass through it.

The techniques of the first embodiment increase the pressure in the enclosed region 407 between the patterning device 401 and the pellicle 402. This may reduce the magnitude of the pressure differences that may occur across the pellicle 402, in particular during spring unloaded calibrations and turnaround situations. Advantageously, this may increase the lifetime of the pellicle 402.

A further advantage of the first embodiment is that some of the gas supplied to the enclosed region 407 may flow through the above described small gaps, or vents, into the illumination region 408. This outflow of gas may prevent any particles in the illumination region 408 from flowing into the enclosed region 407.

FIG. 5 schematically shows a pellicle support system according to a second embodiment. The second embodiment is similar to the first embodiment to the extent that the enclosed region 407 is pressurized so as to reduce the magnitude of pressure differences across the pellicle 402.

The second embodiment differs from the first embodiment in that the gas supply to the enclosed region 407 is independent from the gas supply to the patterning device backside region 406. The gas supply to the enclosed region 407 is provided through the conduit 501. Although not shown in FIG. 5, there is a gas supply to conduit 501 that is separate from the gas supply to the patterning device backside region 406. There may also be a flow control device for controlling the flow of gas through the conduit 501. The flow control device for controlling the flow of gas through the conduit 501 may be the same as that of the first embodiment.

Apart from the supply of gas to the enclosed region 407, the second embodiment may be substantially the same as the first embodiment. In particular, the pressures of the enclosed region 407 may be substantially the same as described for the first embodiment.

The gas supplied to the patterning device backside region 406 is typically hydrogen. If hydrogen is supplied to the enclosed region 407, then there is a risk that the EUV radiation will cause hydrogen radicals to be generated in the enclosed region 407. Standard known pellicles 402 that are already in use in EUV systems may not be substantially damaged by the hydrogen radicals. However, different pellicles 402, that may comprise carbon nanotubes, may also be used in EUV systems. Carbon nanotube pellicles 402 may be damaged by the hydrogen radicals. Accordingly, when carbon nanotube pellicles 402 are used, an inert gas may alternatively be supplied to the enclosed region 407. The EUV radiation is not expected to cause radicals to be generated when an inert gas is used. The use of an inert gas may therefore avoid, or reduce, damage to the carbon nanotube pellicles 402 being caused by the gas supplied to the enclosed region 407. The inert gas may be, for example, nitrogen, argon or helium.

An advantage of the second embodiment is that different gasses may be supplied to the enclosed region 407 and the patterning device backside region 406. This allows carbon nanotube pellicles 402 to be used because hydrogen may be supplied to the patterning device backside region 406 and an inert gas supplied to the enclosed region 407.

In some known systems, a flow of inert gas may be provided, in the illumination region 408, that passes over the surface of the pellicle 402. A further advantage of the second embodiment is that, when a carbon nanotube pellicle 402 is used, the carbon nanotube pellicle 402 may be porous to the inert gas. Some of the inert gas supplied to the enclosed region 407 may therefore flow through the pellicle 402 and into the illumination region 408. The flow of inert gas through the pellicle 402 may avoid, or reduce, the need for providing the known separate flow of inert gas over the surface of the pellicle 402.

The second embodiment may also provide the above-described advantages of the first embodiment.

Embodiments also include a number of modifications and variations to the techniques described above.

In the second embodiment, the conduit 501 may be routed in a number of different ways. In particular, the conduit 501 may alternatively pass through a foot of the pellicle support 405, as described for the conduit 404 of the first embodiment.

In the above description of both of the first and second embodiments, there is only a single conduit 404, 501 for supplying gas to the enclosed region 407. However, in both the first and second embodiments, there may alternatively be more than one conduit 404, 501 for supplying gas to the enclosed region 407. In particular, embodiments include there being conduits 404, 501 through more than one of the feet of the pellicle support 405. Alternatively, the conduit(s) can be provided at various different locations than a feet of the pellicle support in any way as long as the fluid is provided in the volume of the enclosed region between the pellicle and reticle.

In the above description of both of the first and second embodiments, the conduit 404, 501 supplies gas to the enclosed region 407. Both of the first and second embodiments may also include one or more pumps and/or other apparatus for controlling the gas flows so that the conduit 404, 501 may extract gas from the enclosed region 407. This allows the pressure in the enclosed region 407 to be both increased and decreased. The pressure in the enclosed region 407 may be controlled in dependence on the current operational circumstances of the pellicle 402. For example, the pressure in the enclosed region 407 may be increased when a spring unloaded calibration is performed, or during a turnaround situation, and then decreased at other times.

Although embodiments have been described with reference to EUV lithography systems, the pellicle support system of embodiments may be applied in any type of lithography systems, such as DUV lithography systems.

In implementations of both the first and second embodiments, the flow rate of gas through the conduit 404, 501 may be controlled by a variable valve. The operation of the variable valve may be automatically controlled by a control system. Accordingly, the flow rate of gas through the conduit 404, 501 may be varied by the control system controlling the operation of the variable valve.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

While specific embodiments of the invention have been described above, it will be appreciated that the invention may be practiced otherwise than as described. For example, the various photo resist layers may be replaced by non-photo resist layers that perform the same function.

Embodiments include the following numbered clauses:

1. A pellicle support system for use in a lithographic apparatus, the system comprising: a pellicle;
a pellicle support arranged to secure the pellicle relative to the surface of a patterning device so that an enclosed region is defined between the pellicle and the patterning device; and
at least one conduit arranged to supply fluid to the enclosed region for increasing the pressure in the enclosed region.
   2. The pellicle support system according to clause 1, further comprising a flow control device arranged to control the rate and/or duration of fluid flow through the at least one conduit 404.
   3. The pellicle support system according to clause 2, wherein the flow control device is arranged to control the supply of fluid through the at least one conduit so that the pressure of the enclosed region is about 0.2 Pa to 5 Pa, and preferably about 1 Pa, higher than if there was no fluid supplied to the enclosed region through the at least one conduit.
   4. The pellicle support system according to any preceding clause, wherein the supplied fluid to the enclosed region is a gas.
   5. The pellicle support system according to any preceding clause, wherein the system comprises a plurality of conduits arranged to supply fluid to the enclosed region.
   6. The pellicle support system according to any preceding clause, wherein each conduit is provided through a foot of the pellicle support.
   7. The pellicle support system according to any of clauses 2 to 6, wherein the flow control device is an orifice with a fixed shape.
   8. The pellicle support system according to any of clauses 2 to 6, wherein the flow control device is a variable valve; and the flow rate of fluid through the conduit is controllable in dependence on the operation of the variable valve.
   9. The pellicle support system according to any preceding clause, wherein there is a patterning device backside region that is on the opposite side of the patterning device to the pellicle and a fluid source arranged to supply fluid to the patterning device backside region; and the conduit is arranged to provide a flow path of fluid from the patterning device backside region to the enclosed region.
   10. The pellicle support system according to clause 9, wherein the supplied fluid to the enclosed region is hydrogen.
   11. The pellicle support system according to any of clauses 1 to 8, wherein there is a patterning device backside region that is on the opposite side of the patterning device to the pellicle and a first fluid source arranged to supply fluid to the patterning device backside region; and the conduit is arranged to provide a flow path of fluid from a second fluid source, that is separate from the first fluid source, to the enclosed region.
   12. The pellicle support system according to clause 11, wherein the supplied fluid to the enclosed region is an inert gas.
   13. The pellicle support system according to clause 11 or 12, wherein the pellicle comprises carbon nanotubes.
   14. The pellicle support system according to any preceding clause, wherein the lithographic apparatus is an EUV lithographic apparatus.
   15. A lithographic apparatus comprising the pellicle support system according to any preceding clause.
   16. A method for performing lithography, the method comprising projecting a radiation beam through a low pressure environment onto a substrate in an exposure operation;
wherein the radiation beam passes through a pellicle located in the low pressure environment; and the pellicle is comprised by the pellicle support system according to any of clauses 1 to 14.
   17. The method according to clause 16, wherein the radiation beam is an EUV radiation beam.

The descriptions above are intended to be illustrative, not limiting. Thus it will be apparent to one skilled in the art that modifications may be made to the invention as described without departing from the scope of the claims set out below.

1. A pellicle support system for use in a lithographic apparatus, the pellicle support system comprising:
a pellicle;
a pellicle support arranged to secure the pellicle relative to a surface of a patterning device so that an enclosed region is defined between the pellicle and the patterning device; and
at least one conduit arranged to supply fluid to the enclosed region to increase the pressure in the enclosed region.

2. The pellicle support system according to claim 1, further comprising a flow control device arranged to control the rate and/or duration of fluid flow through the at least one conduit.

3. The pellicle support system according to claim 2, wherein the flow control device is arranged to control the supply of fluid through the at least one conduit so that the pressure of the enclosed region is about 0.2 Pa to 5 Pa, higher than if there was no fluid supplied to the enclosed region through the at least one conduit.

4. The pellicle support system according to claim 1, wherein the supplied fluid to the enclosed region is a gas.

5. The pellicle support system according to claim 1, comprising a plurality of conduits arranged to supply fluid to the enclosed region.

6. The pellicle support system according to claim 1, wherein each conduit is provided through a foot of the pellicle support.

7. The pellicle support system according to claim 2, wherein the flow control device is an orifice with a fixed shape.

8. The pellicle support system according to claim 2, wherein the flow control device is a variable valve; and wherein the flow rate of fluid through the conduit is controllable in dependence on operation of the variable valve.

9. The pellicle support system according to claim 1, wherein there is a patterning device backside region that is on the opposite side of the patterning device to the pellicle; and
wherein the conduit is arranged to provide a flow path of fluid from the patterning device backside region to the enclosed region.

10. The pellicle support system according to claim 9, wherein the supplied fluid to the enclosed region is hydrogen.

11. The pellicle support system according to claim 1, wherein there is a patterning device backside region that is on the opposite side of the patterning device to the pellicle; and
the conduit is arranged to provide a flow path of fluid from a second fluid source, that is separate from a first fluid source arranged to supply fluid to the patterning device backside region, to the enclosed region.

12. The pellicle support system according to claim 11, wherein the supplied fluid to the enclosed region is an inert gas.

13. The pellicle support system according to claim 11, wherein the pellicle comprises carbon nanotubes.

14. The pellicle support system according to claim 1, wherein the lithographic apparatus is an EUV lithographic apparatus.

15. A lithographic apparatus comprising the pellicle support system according to claim 1.

16. A method for performing lithography, the method comprising projecting a radiation beam through a low pressure environment onto a substrate in an exposure operation,
wherein the radiation beam passes via the pellicle support system according to claim 1, the pellicle located in the low pressure environment.

17. The method according to claim 16, wherein the radiation beam is an EUV radiation beam.

18. The method according to claim 16, further comprising controlling, using a flow control device, the rate and/or duration of fluid flow through the at least one conduit.

19. The method according to claim 16, wherein each conduit is provided through a foot of the pellicle support.

20. The method according to claim 16, wherein the conduit is arranged to provide a flow path of fluid from a patterning device backside region to the enclosed region, the patterning device backside region being on the opposite side of the patterning device to the pellicle.
